(19) United States
(12) Patent Application Publication
(10) Pub. No.: US 2025/0057047 A1
(43) Pub. Date: Feb. 13, 2025

(54) PREPARATION METHOD AND USE OF TUNABLE TRANSPARENT TERAHERTZ ABSORPTION FILM FOR ENHANCING THERMAL RADIATION

(71) Applicant: ZHEJIANG UNIVERSITY, Hangzhou (CN)

(72) Inventors: Wendao XU, Hangzhou (CN); Haolan WANG, Hangzhou (CN); Lijuan XIE, Hangzhou (CN); Yibin YING, Hangzhou (CN)

(73) Assignee: ZHEJIANG UNIVERSITY, Hangzhou (CN)

(21) Appl. No.: 18/770,720

(22) Filed: Jul. 12, 2024

Related U.S. Application Data
(63) Continuation of application No. PCT/CN2023/143377, filed on Dec. 29, 2023.

(30) Foreign Application Priority Data
Aug. 9, 2023 (CN) 202310998725.3

(51) Int. Cl. H10N 15/10; A01G 9/14; A01G 9/24; C23C 14/02; C23C 14/08; C23C 14/34; C23C 16/26; C23C 28/04; F24S 70/225

(52) U.S. Cl. CPC H10N 15/15; A01G 9/1438; C23C 14/021; C23C 14/086; C23C 14/34; C23C 16/26; C23C 28/04; F24S 70/225; A01G 9/243

(57) ABSTRACT

A preparation method a tunable transparent terahertz absorption film for enhancing thermal radiation includes: evaporating/sputtering an indium tin oxide (ITO) on one surface of a polyimide film, transferring graphene to the other surface of the polyimide film, preparing one electrode on the graphene, spin-coating an ionic gel, and preparing the other electrode on the ionic gel to form the tunable transparent terahertz absorption film; and changing bias voltages at two ends of the electrode, acquiring a terahertz time-domain signal of the tunable transparent terahertz absorption film to derive an absorption rate of the tunable transparent terahertz absorption film corresponding to the bias voltages, and placing the tunable transparent terahertz absorption film under sunlight/infrared light to acquire a heating effect. The preparation method utilizes the transparent absorption film of a graphene-polyimide-ITO structure to absorb terahertz waves of multiple bands, improving the heating effect.

### CROSS REFERENCE TO THE RELATED APPLICATIONS

This application is the continuation application of International Application No. PCT/CN2023/143377, filed on Dec. 29, 2023, which is based upon and claims priority to Chinese Patent Application No. 202310998725.3, filed on Aug. 9, 2023, the entire contents of which are incorporated herein by reference.

### TECHNICAL FIELD

The present disclosure belongs to the technical field of thermal insulation films, and in particular to a preparation method and use of a tunable transparent terahertz absorption film for enhancing thermal radiation.

### BACKGROUND

In China, with the continuous improvement of living standards, peoples' demand for out-of-season fruits/vegetables is gradually increasing. To ensure the normal growth of out-of-season fruits/vegetables in the greenhouse, it is necessary to consume a large amount of energy to increase the temperature inside the greenhouse. By improving the lighting angle, thermal insulation and heat storage performance, existing greenhouses can achieve normal production in a −20° C. environment. However, the greenhouse film still has a high transmittance to infrared waves, making it hard to utilize infrared wave energy (such as terahertz band energy). Therefore, it is highly desirable to develop a greenhouse film with high transmittance to visible light and the ability to utilize infrared wave energy. This greenhouse film can ensure the normal growth of out-of-season fruits/vegetables in the greenhouse and effectively reduce energy consumption and greenhouse gas emissions, thereby achieving passive energy conservation and supporting the “dual carbon goals”. However, there is a lack of a greenhouse film for efficiently utilizing infrared wave energy in the prior art.

### SUMMARY

In order to solve the problems mentioned in the Background section, an objective of the present disclosure is to provide a preparation method and use of a tunable transparent terahertz absorption film for enhancing thermal radiation. The method of the present disclosure features dynamic tuning, high terahertz absorption rate, and simple preparation steps.

The present disclosure adopts the following technical solutions. The method includes the following steps.

In a first step, a tunable transparent terahertz absorption film is prepared, where the tunable transparent terahertz absorption film includes an electrode, an ionic gel, an electrode, graphene, a transparent polyimide film, and an indium tin oxide (ITO) in sequence from top to bottom;
in the first step, the tunable transparent terahertz absorption film is prepared as follows:
step 1): evaporating/sputtering the ITO on a surface of a dielectric film;
taking a cleaned transparent polyimide film, and evaporating/sputtering the ITO on a lower surface of the polyimide film;
step 2): transferring the graphene to an upper surface of the polyimide film;
step 3): preparing a first electrode at an end of an upper surface of the graphene;
step 4): spin-coating the ionic gel on the upper surface of the graphene; and
step 5): preparing a second electrode on an upper surface of the ionic gel, finally forming the tunable transparent terahertz absorption film.

The dielectric film is the polyimide film; and
in the step 1), the transparent polyimide film is cleaned as follows: taking a complete polyimide film; cleaning the polyimide film with acetone, isopropanol, and deionized water in sequence; and blow-drying the polyimide film with nitrogen to acquire the cleaned polyimide film.

The polyimide film has a thickness of 10-200 μm.

In the step 1), the ITO has a thickness of 50-300 nm.

In the step 2), the graphene is prepared by chemical vapor deposition (CVD) or mechanical exfoliation, and the graphene includes 1-5 layers.

In the step 4), the ionic gel is spin-coated at 1,500-4,000 r.p.m.

In the step 4), the ionic gel is spin-coated to cover the first electrode prepared in the step 3); and
the first electrode and the second electrode are located at two sides of the tunable transparent terahertz absorption film, respectively.

In the step 2), specifically, the graphene is transferred to the polyimide film as follows:
adding the graphene into water for at least 2 h; clamping, by tweezers, the polyimide film coated with the ITO, and putting the polyimide film obliquely into the water; attaching a side of the polyimide film not coated with the ITO to the graphene in the water; adjusting the graphene to a middle position of the polyimide film, taking the polyimide film attached with the graphene out of the water, and placing the polyimide film vertically for 3-5 min to drain excess water; allowing the polyimide film to stand for an airing purpose for 30-40 min; and drying the polyimide film in an oven at 100-120° C. for 20-30 min to acquire a dry polyimide film attached with the graphene.

The polyimide film is used for preparing a radiation heating device, warm clothing, or a greenhouse.

In a second step, thermal radiation absorption efficiency of the tunable transparent terahertz absorption film is verified:
step 1): acquiring a terahertz time-domain signal of the tunable transparent terahertz absorption film:
acquiring terahertz time-domain signals of the tunable transparent terahertz absorption film and a total internal reflection mirror in a spectral bandwidth range of 0.1-10 THz in a nitrogen atmosphere;
step 2): changing bias voltages at two ends of the electrode, and acquiring a terahertz time-domain signal of the tunable transparent terahertz absorption film;
where, in the step 1), when the terahertz time-domain signal of the tunable transparent terahertz absorption film is acquired, ambient humidity is less than 2%; and in the step 2), the bias voltages at two ends of each of the two electrodes is-3.0 V to 3.0 V;
step 3): acquiring an absorption peak intensity of the tunable transparent terahertz absorption film from based on the terahertz time-domain signal:
converting the terahertz time-domain signal into a frequency-domain signal through a fast Fourier transform; and acquiring, based on the frequency-domain signal, an absorption rate of the tunable transparent terahertz absorption film corresponding to the bias voltages; and
step 4): placing the tunable transparent terahertz absorption film and an ordinary film under sunlight/infrared light, and monitoring temperature rises of the tunable transparent terahertz absorption film and the ordinary film.

Preferably, in a specific implementation of the graphene according to the present disclosure, the graphene can be, but is not limited to, Trivial Transfer Graphene produced by ACS Material; and the graphene can be replaced by a semi-metal, such as tungsten ditelluride.

Preferably, in a specific implementation of the ionic liquid of the present disclosure, the ionic liquid can be, but is not limited to, 711691-100G ionic liquid produced by Sigma Corporation.

Preferably, in a specific implementation of poly(vinylidene fluoride-co-hexafluoropropylene) (P(VDF-HFP)) of the present disclosure, the P(VDF-HFP) can be, but is not limited to, 427160-100G P(VDF-HFP) produced by Sigma Corporation.

Preferably, in a specific implementation of an infrared camera of the present disclosure, the infrared camera can be, but is not limited to, DS-2TD2636-10 infrared camera produced by Hikvision.

Preferably, in a specific implementation of the polyimide film of the present disclosure, the polyimide film can be, but is not limited to, a transparent polyimide film produced by Huanan Xiangcheng Technology Company; and the polyimide film can be replaced by other dielectric materials such as photoresist, for example, SU-8 photoresist, polyethylene terephthalate (PET).

The thickness of the ITO is at least 50 nm. If the thickness of the ITO is less than 50 nm, terahertz waves can pass through the ITO, resulting in a weakened terahertz radiation absorption effect of the transparent terahertz absorption film.

The transparent terahertz absorption film using the ionic gel can achieve large-amplitude modulation of terahertz waves through a low voltage (<3 V). Compared with laser modulation and ordinary voltage modulation (modulation voltage reaching tens or even hundreds of volts), the large-amplitude modulation method features simple equipment and safe operation.

Compared with traditional terahertz absorption films, the transparent terahertz absorption film has high transmittance, allowing visible light to pass through the ionic gel, the graphene, the dielectric material, and the ITO. Since terahertz waves cannot pass through the ITO, the terahertz wave of multiple frequency bands incident on the transparent terahertz absorption film will be absorbed by an absorber structure formed by the graphene, the dielectric material, and the ITO. In addition, the bias voltages are applied to the upper and lower sides of the ionic gel to adjust the absorption rate. In summary, the transparent terahertz absorption film can enhance the absorption and utilization of terahertz waves without affecting crop photosynthesis.

Preferably, in a specific implementation of the present disclosure, it is recommended to use a TAS7500 terahertz time-domain spectroscopy (THz-TDS) system terahertz time-domain spectral system produced by ADVANTEST Corporation.

Terahertz waves refer to electromagnetic waves with frequencies of 0.1-10 THz (1 THz=1,012 Hz), belonging to the far-infrared band. Terahertz waves are widely present in nature, and the energy in this band is included in human body radiation. The THz-TDS technology used in the present disclosure has been rapidly developed and promoted internationally in recent years.

In the present disclosure, the tunable transparent terahertz absorption film uses a graphene-dielectric material-ITO anti-transmission layer structure. It has a high transmittance in the visible light band and meets impedance matching conditions in the terahertz band. It can absorb terahertz waves from multiple bands and convert them into thermal energy, improving the heating effect. Since terahertz waves have strong penetration into dielectric materials such as plastics and clothing, ordinary plastic agricultural films are hard to absorb and utilize terahertz energy, reducing the heating effect of the greenhouse.

The outstanding advantage of the tunable transparent terahertz absorption film in the present disclosure lies in the high transmittance to visible light and the ability to absorb terahertz waves from multiple bands and convert them into thermal energy. The absorption film avoids periodic photolithography of a metal structure, has a flat surface, and is easy to process.

In the present disclosure, the tunable transparent terahertz absorption film technology has the following beneficial effects.

1. In the present disclosure, the tunable transparent terahertz absorption film utilizes a transparent graphene-polyimide-ITO absorber structure to absorb terahertz waves of multiple bands, improving the heating effect.

2. Compared with traditional plastic films, the tunable transparent terahertz absorption film in the present disclosure can significantly improve the utilization of far-infrared radiation and enhance the heating effect. Compared with ordinary terahertz absorbers, the tunable transparent terahertz absorption film in the present disclosure avoids a photolithography step, has high transmittance to visible light, simplifies device preparation, and can meet the growing demand for passive energy conservation.

### BRIEF DESCRIPTION OF THE DRAWINGS

FIG. 1 is a structural diagram of a tunable transparent terahertz absorption film according to the present disclosure;

FIG. 2 shows terahertz transmission and reflection curves of an ITO according to the present disclosure;

FIG. 3 shows terahertz reflection curves of the transparent terahertz absorption film and a dielectric layer-ITO structure according to the present disclosure;

FIG. 4 shows terahertz reflection curves of the tunable transparent terahertz absorption film under different bias voltages according to Embodiment 1 of the present disclosure;

FIG. 5 shows simulated terahertz reflection curves of the tunable transparent terahertz absorption film at different Fermi levels according to Embodiment 1 of the present disclosure;

FIG. 6 shows changes in reflectivity of the tunable transparent terahertz absorption film at a lowest point under different bias voltages according to Embodiment 1 of the present disclosure;

FIG. 7 shows simulated reflectivity of the transparent terahertz absorption film in a 0.2-5 THz band according to Embodiment 2 of the present disclosure;

FIG. 8 shows temperature change trends of the transparent terahertz absorption film and glass in a heating process under infrared light according to Embodiment 2 of the present disclosure;

FIG. 9 shows transmittance of the transparent terahertz absorption film in a visible light band according to Embodiment 2 of the present disclosure; and

FIG. 10 shows simulated terahertz reflection curves of tunable transparent terahertz absorption films with dielectric layers of different thicknesses according to Embodiment 3 of the present disclosure.

Reference Numerals: 1. electrode; 2. graphene; 3. ionic gel; 4. polyimide; and 5. ITO.

### DETAILED DESCRIPTION OF THE EMBODIMENTS

The present disclosure is described in detail below according to specific embodiments. The following embodiments will help those skilled in the art to further understand the present disclosure, rather than to limit the present disclosure in any way.

### Embodiment 1

### (1) Preparation of Tunable Transparent Terahertz Absorption Film

A polyimide film with a thickness of 50 mm is ultrasonically cleaned in acetone, isopropanol, and water in sequence, 10 min for each cleaning agent, and is blown-dry with nitrogen to acquire a cleaned polyimide film. ITO 5 with a thickness of 50-300 nm is evaporated/sputtered on the surface of the polyimide film, and a layer of graphene 2 is transferred to the other side of the polyimide film. The graphene is transferred as follows.

Purchased graphene is added into water for at least 2 h. Then the polyimide film is clamped with tweezers and put obliquely into the water. If necessary, another pair of tweezers can be used to press the polyimide film into water. The side of the polyimide film not coated with the ITO 5 is attached to the graphene in the water. The graphene is adjusted to an appropriate position and then is taken out of the water. The polyimide film is placed vertically for 3 min to drain excess water, and stands for 30 min for an airing purpose. Then the polyimide film is dried in an oven at 100° C. for 20 min, and stands till room temperature. The polyimide film is soaked in acetone for about 10 min. One electrode 1 is prepared on the monolayer graphene 2 by a conductive silver adhesive.

### (2) Preparation of Ionic Gel 3

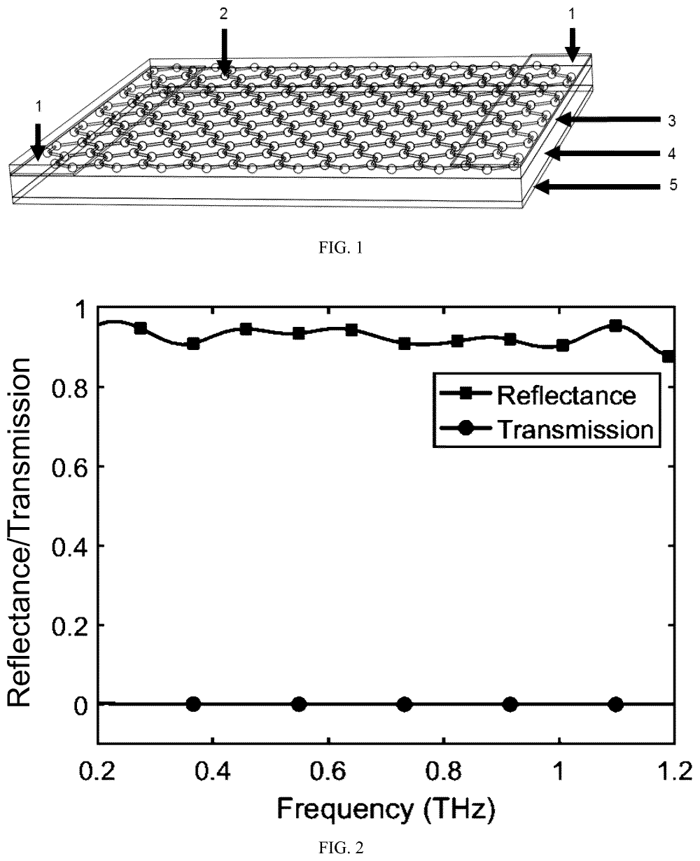

P(VDF-HFP) and ionic liquid [EMI] [TFSA] are dissolved in an acetone solvent to acquire an ionic gel solution. A weight ratio of the copolymer, the ionic liquid, and the solvent is set to 1:4:7. The ionic gel solution is stirred at 50° C. for 2 h to form a uniform solution. The ionic gel solution is spin-coated on the monolayer graphene at 2,500 r.p.m. To remove the acetone solvent, the polyimide film is heated at 70° C. for 24 h. The other electrode 1 is prepared on the ionic gel 3 by the conductive silver adhesive to form a tunable transparent terahertz absorption film. The structure of the tunable transparent terahertz absorption film is shown in FIG. 1.

### (3) Electrical Modulation of Active Layer

The graphene layer, the ionic gel layer, and the silver electrodes form an active layer that can realize terahertz wave modulation in a reflection mode. When there is no bias voltage (Vg=0), free cations and anions are randomly distributed in the ionic gel. An external bias voltage is applied to the active layer to make the silver electrode generate an electric field and attract ions with opposite charges from the ionic gel, thereby forming a thin electric double layer (EDL) close to the graphene and the upper electrode. Through this structure, a high-strength electric field is formed next to the graphene, leading to a rapid increase in the carrier concentration on the graphene.

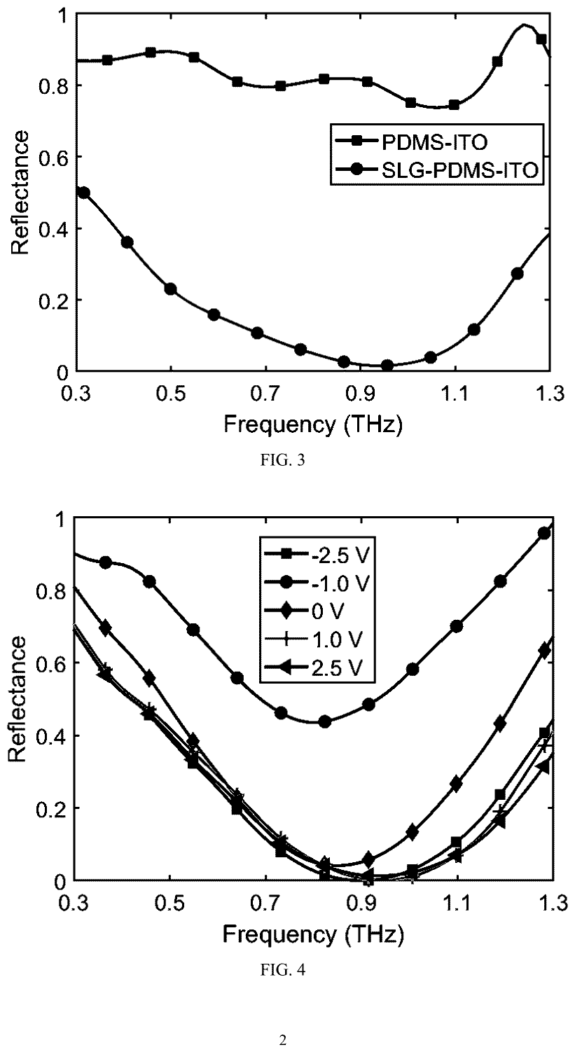

Based on the above principles, when the impedance matching conditions change, the reflectivity of the tunable transparent terahertz absorption film will undergo significant changes. Therefore, the Fermi level of the graphene can be effectively modulated by a small electric bias voltage (<3 V), achieving efficient terahertz wave modulation. The terahertz transmission and reflection curves of the ITO and the terahertz reflection curves of the transparent terahertz absorption film and the dielectric layer-ITO structure are shown in FIGS. 2 and 3, respectively.

### (4) Measurement of Tunable Transparent Terahertz Absorption Film Under Different Bias Voltages by THz-TDS System

The reflectivity of the tunable transparent terahertz absorption film under different bias voltages is measured by a THz-TDS system. As shown in FIG. 4, the results show that when the bias voltage increases from −2.5 V to 2.5 V, the reflectivity of the tunable transparent terahertz absorption film varies within 0-0.42. Due to the p-doping characteristics of the graphene in air, the reflectivity is not at its highest point at 0 V.

### (5) Finite-Difference Time-Domain (FDTD) Simulation on Reflectivity of Tunable Transparent Terahertz Absorption Film at Different Fermi Levels

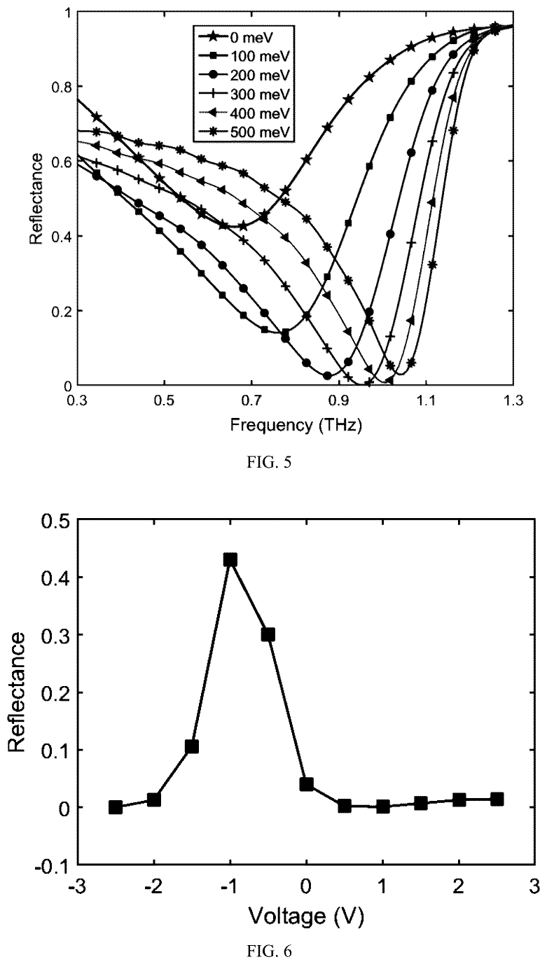

The Fermi levels of the graphene are set to 0-500 meV, and FDTD simulations are performed correspondingly. As shown in FIG. 5, the results show that as the Fermi level increases from 0 meV to 300 meV, the reflectivity of the tunable transparent terahertz absorption film decreases from 0.42 to 0 (almost perfect absorption), and the impedance mismatch of the tunable transparent terahertz absorption film decreases until it approaches 0. By further increasing the Fermi level, impedance mismatch increases, leading to an increase in reflectivity.

### (6) Changes in Reflectivity of Tunable Transparent Terahertz Absorption Films Under Different Bias Voltages

Changes in the reflectivity of the tunable transparent terahertz absorption film under different bias voltages are further plotted. As shown in FIG. 6, the results show that when the bias voltage is set to −1.0 V, the terahertz reflectivity reaches a maximum value (0.42), indicating that the Fermi level of the monolayer graphene is close to a charge neutral point (CNP).

The tunable transparent terahertz absorption film prepared by the present disclosure can be modulated by applying a small voltage. Since the electrochemical window is small, larger bias voltages (>3 V) should be avoided, otherwise irreversible damage will be caused to the ionic gel.

### Embodiment 2

### (1) Preparation of Tunable Transparent Terahertz Absorption Film

A polyimide film with a thickness of 50 mm is ultrasonically cleaned in acetone, isopropanol, and water in sequence, 10 min for each cleaning agent, and is blown-dry with nitrogen to acquire a cleaned polyimide film. ITO with a thickness of 50-300 nm is evaporated/sputtered on the surface of the polyimide film, and a layer of graphene 2 is transferred to the other side of the polyimide film. The graphene is transferred as follows.

Purchased graphene is added into water for at least 2 h. Then the polyimide film is clamped with tweezers and put obliquely into the water. If necessary, another pair of tweezers can be used to press the polyimide film into water. The side of the polyimide film not coated with the ITO 5 is attached to the graphene in the water. The graphene is adjusted to an appropriate position and then is taken out of the water. The polyimide film is placed vertically for 3 min to drain excess water, and stands for 30 min for an airing purpose. Then the polyimide film is dried in an oven at 100° C. for 20 min, and stands till room temperature. The polyimide film is soaked in acetone for about 10 min. One electrode 1 is prepared on the graphene 2 by a conductive silver adhesive. The ionic gel solution is spin-coated on the monolayer graphene 2 at 3,500 r.p.m. The other electrode 1 is prepared on the ionic gel 3 by the conductive silver adhesive to form a tunable transparent terahertz absorption film.

### (2) Simulation on Heating of Tunable Transparent Terahertz Absorption Film

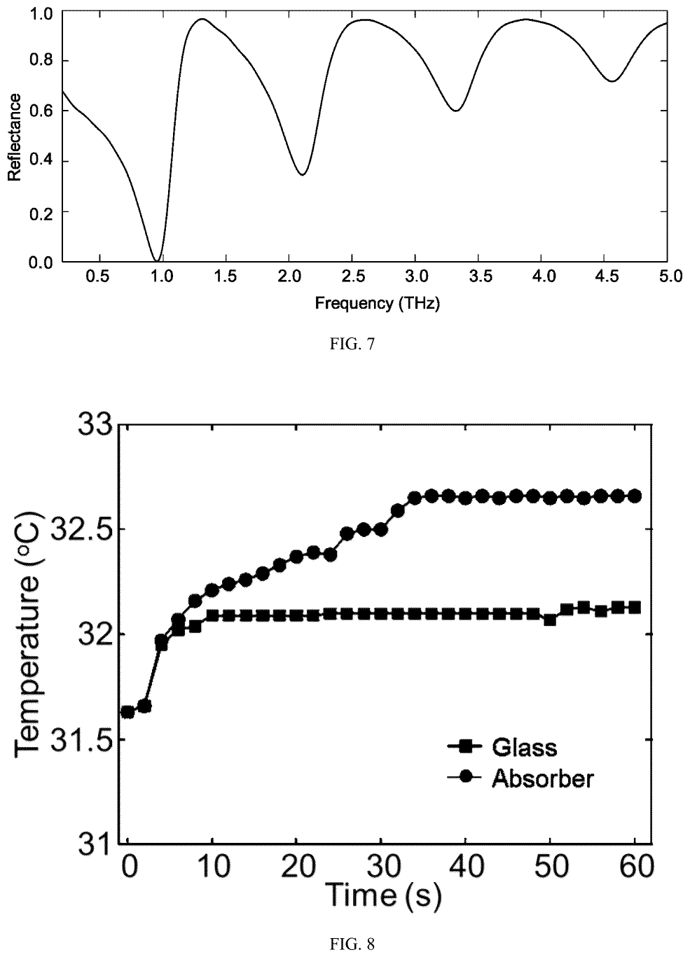

Compared with a greenhouse that only uses glass, in the conditions of meeting impedance matching requirements and absorbing incident radiation at corresponding frequencies, a greenhouse that uses the transparent terahertz absorption films has the potential to achieve better heating performance and convert external radiation into thermal energy. As shown in FIG. 7, simulation results show that the transparent terahertz absorption film can absorb multiple frequency bands of terahertz waves such as 0.95, 2.10, 3.33, and 4.57 THz, and the absorption peaks are almost uniformly distributed. This is attributed to the multiple reflections in the cavity of the transparent terahertz absorption film, which behaves similarly to the Fabry-Perot cavity (F-P cavity). As the frequency increases, the absorption intensity weakens due to the damped resonance intensity of the F-P cavity. The multi-band absorption also indicates that the device can convert a wide range of terahertz radiation into thermal energy.

### (3) Comparison of Infrared Radiation Heating Between Transparent Terahertz Absorption Film and Glass

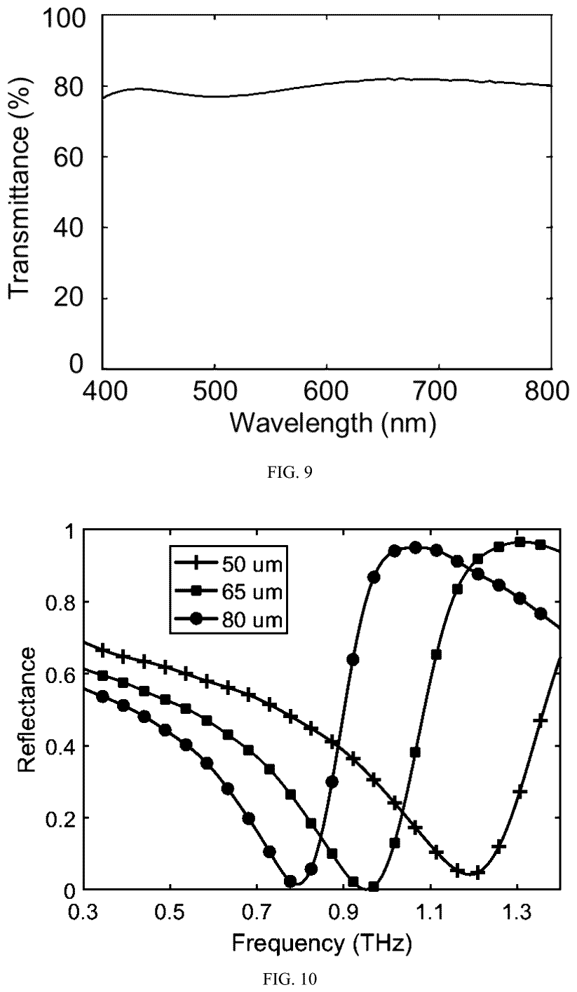

To further illustrate the radiation heating effect of the device, external heating radiation is provided by an infrared light source, and surface temperature changes of the transparent terahertz absorption film and the glass during the irradiation process of the infrared light source are recorded by an infrared camera. As shown in FIG. 8, the results show that the surface temperatures of the transparent terahertz absorption film and the glass increase in a similar trend in the first 5 s. Subsequently, the surface temperature of the glass reaches a threshold, and the surface temperature of the transparent terahertz absorption film continues to rise. After equilibrium (35 s), the surface temperature of the transparent terahertz absorption film is 0.7° C. higher than that of the glass. The transparent terahertz absorption film has a higher transmittance in the visible light band, as shown in FIG. 9. Therefore, the transparent terahertz absorption film has the potential to capture infrared radiation energy and can be used for multiple purposes, for example, to fabricate radiation heating devices, warm clothing and greenhouses.

### (4) Preparation of Glass Terahertz Absorber

A polydimethylsiloxane (PDMS) base solution and a curing agent are mixed in a weight ratio of 15:1 to prepare a PDMS solution. The solution is spin-coated onto an ITO/glass substrate at 2,500 r.p.m. Then heating is performed at 60° C. for 1 h, and a layer of graphene is transferred to a surface of the PDMS.

The graphene is transferred as follows.

Purchased graphene is added into water for at least 2 h. Then the ITO/glass substrate attached with the PDMS layer is clamped with tweezers to attach the graphene in the water. The graphene is adjusted to an appropriate position and then is taken out of the water. The ITO/glass substrate is placed vertically for 3 min to drain excess water, and stands for 30 min for an airing purpose. Then the ITO/glass substrate is dried in an oven at 100° C. for 20 min, and stands till room temperature. The ITO/glass substrate is soaked in acetone for about 10 min to remove a polymethyl methacrylate (PMMA) protection layer on the surface. The graphene absorber is taken out, cleaned with deionized water, and blown-dry by nitrogen. An electrode is prepared on the monolayer graphene by a conductive silver adhesive.

### (5) Preparation of Ionic Gel

P(VDF-HFP) and ionic liquid [EMI] [TFSA] are dissolved in an acetone solvent to acquire an ionic gel solution. A weight ratio of the copolymer, the ionic liquid, and the solvent is set to 1:4:7. The solution is stirred at 50° C. for 2 h to form a uniform solution. The ionic gel solution is spin-coated on the monolayer graphene at 2,500 r.p.m. To remove the acetone solvent, the ITO/glass substrate is heated at 70° C. for 24 h. The other electrode is prepared on the ionic gel by a conductive silver adhesive, thereby finally forming the glass terahertz absorber.

### Embodiment 3

### (1) Preparation of Tunable Transparent Terahertz Absorption Film

A PET film with a thickness of 50 mm is ultrasonically cleaned in acetone, isopropanol, and water in sequence, 10 min for each cleaning agent, and is blown-dry with nitrogen to acquire a cleaned PET film. ITO 5 with a thickness of 50-300 nm is evaporated/sputtered on the surface of the PET film, and a layer of graphene 2 is transferred to the other side of the PET film.

The graphene 2 is transferred as follows.

Purchased graphene is added into water for at least 2 h. Then the PET film is clamped with tweezers and put obliquely into the water. If necessary, another pair of tweezers can be used to press the PET film into water. The side of the PET film not coated with the ITO 5 is attached to the graphene in the water. The graphene is adjusted to an appropriate position and then is taken out of the water. The PET film is placed vertically for 3 min to drain excess water, and stands for 30 min for an airing purpose. Then the PET film is dried in an oven at 100° C. for 20 min, and stands till room temperature. The PET film is soaked in acetone for about 10 min. One electrode 1 is prepared on the monolayer graphene 2 by a conductive silver adhesive.

### (2) Preparation of Ionic Gel

P(VDF-HFP) and ionic liquid [EMI] [TFSA] are dissolved in an acetone solvent to acquire an ionic gel solution. A weight ratio of the copolymer, the ionic liquid, and the solvent is set to 1:4:7. The ionic gel solution is stirred at 50° C. for 2 h to form a uniform solution. The ionic gel solution is spin-coated on the monolayer graphene at 2,500 r.p.m. To remove the acetone solvent, the PET film is heated at 70° C. for 24 h. The other electrode is prepared on the ionic gel by the conductive silver adhesive to form a tunable transparent terahertz absorption film. The preparation of the tunable transparent terahertz absorption film is now completed. The simulated terahertz reflection curves of transparent terahertz absorption films with different thicknesses are shown in FIG. 10.

From the above implementations, it can be seen that in the present disclosure, the transparent terahertz absorption film has high transmittance in the visible light band and strong absorption in the terahertz band, enhancing the thermal radiation absorption effect. The present disclosure is expected to reduce energy consumption and greenhouse gas emissions, and the preparation method is simple, which meets the growing demand for passive energy conservation.

The above specific implementations are intended to explain the present disclosure, rather than to limit the present disclosure. Within the spirit of the present disclosure and the protection scope of the claims, any modification and change to the present disclosure should fall into the protection scope of the present disclosure.

What is claimed is:

1. A preparation method of a tunable transparent terahertz absorption film for enhancing thermal radiation, comprising the following steps:
step 1): evaporating/sputtering an indium tin oxide (ITO) on a surface of a cleaned dielectric film:
taking the cleaned dielectric film, and evaporating/sputtering the ITO on a lower surface of the cleaned dielectric film;
step 2): transferring graphene to an upper surface of the cleaned dielectric film;
step 3): preparing a first electrode at an end of an upper surface of the graphene;
step 4): spin-coating an ionic gel on the upper surface of the graphene; and
step 5): preparing a second electrode on an upper surface of the ionic gel, finally forming the tunable transparent terahertz absorption film.

2. The preparation method of the tunable transparent terahertz absorption film for enhancing thermal radiation according to claim 1, wherein the cleaned dielectric film is a transparent polyimide film; and
in the step 1), the transparent polyimide film is cleaned as follows: taking a complete polyimide film; cleaning the complete polyimide film with acetone, isopropanol, and deionized water in sequence; and blow-drying the complete polyimide film with nitrogen to acquire a cleaned polyimide film.

3. The preparation method of the tunable transparent terahertz absorption film for enhancing thermal radiation according to claim 2, wherein the transparent polyimide film has a thickness of 10 μm-200 μm.

4. The preparation method of the tunable transparent terahertz absorption film for enhancing thermal radiation according to claim 1, wherein in the step 1), the ITO has a thickness of 50 nm-300 nm.

5. The preparation method of the tunable transparent terahertz absorption film for enhancing thermal radiation according to claim 1, wherein in the step 2), the graphene is prepared by chemical vapor deposition (CVD) or mechanical exfoliation, and the graphene comprises 1-5 layers.

6. The preparation method of the tunable transparent terahertz absorption film for enhancing thermal radiation according to claim 1, wherein in the step 4), the ionic gel is spin-coated at 1,500 r.p.m-4,000 r.p.m.

7. The preparation method of the tunable transparent terahertz absorption film for enhancing thermal radiation according to claim 1, wherein in the step 4), the ionic gel is spin-coated to cover the first electrode prepared in the step 3).

8. The preparation method of the tunable transparent terahertz absorption film for enhancing thermal radiation according to claim 1, wherein the first electrode and the second electrode are located at two sides of the tunable transparent terahertz absorption film, respectively.

9. The preparation method of the tunable transparent terahertz absorption film for enhancing thermal radiation according to claim 2, wherein in the step 2), the step of transferring the graphene to the upper surface of the cleaned dielectric film comprises:
adding the graphene into water for at least 2 h; clamping, by tweezers, the polyimide film coated with the ITO, and putting the polyimide film obliquely into the water; attaching a side of the polyimide film to the graphene in the water, wherein the side of the polyimide film is not coated with the ITO; adjusting the graphene to a middle position of the polyimide film, taking the polyimide film attached with the graphene out of the water, and placing the polyimide film vertically for 3 min-5 min to drain excess water; allowing the polyimide film to stand for an airing purpose for 30 min-40 min; and drying the polyimide film in an oven at 100° C.-120° C. for 20 min-30 min to acquire a dry polyimide film attached with the graphene.

10. A use of the polyimide film prepared by the preparation method according to claim 1 in preparation of a radiation heating device.

11. The use of the polyimide film according to claim 10, wherein the cleaned dielectric film is a transparent polyimide film; and
in the step 1), the transparent polyimide film is cleaned as follows: taking a complete polyimide film; cleaning the complete polyimide film with acetone, isopropanol, and deionized water in sequence; and blow-drying the complete polyimide film with nitrogen to acquire a cleaned polyimide film.

12. The use of the polyimide film according to claim 11, wherein the transparent polyimide film has a thickness of 10 μm-200 μm.

13. The use of the polyimide film according to claim 10, wherein in the step 1), the ITO has a thickness of 50 nm-300 nm.

14. The use of the polyimide film according to claim 10, wherein in the step 2), the graphene is prepared by chemical vapor deposition (CVD) or mechanical exfoliation, and the graphene comprises 1-5 layers.

15. The use of the polyimide film according to claim 10, wherein in the step 4), the ionic gel is spin-coated at 1,500 r.p.m-4,000 r.p.m.

16. The use of the polyimide film according to claim 10, wherein in the step 4), the ionic gel is spin-coated to cover the first electrode prepared in the step 3).

17. The use of the polyimide film according to claim 10, wherein the first electrode and the second electrode are located at two sides of the tunable transparent terahertz absorption film, respectively.

18. The use of the polyimide film according to claim 11, wherein in the step 2), the step of transferring the graphene to the upper surface of the cleaned dielectric film comprises:
adding the graphene into water for at least 2 h; clamping, by tweezers, the polyimide film coated with the ITO, and putting the polyimide film obliquely into the water; attaching a side of the polyimide film to the graphene in the water, wherein the side of the polyimide film is not coated with the ITO; adjusting the graphene to a middle position of the polyimide film, taking the polyimide film attached with the graphene out of the water, and placing the polyimide film vertically for 3 min-5 min to drain excess water; allowing the polyimide film to stand for an airing purpose for 30 min-40 min; and drying the polyimide film in an oven at 100° C.-120° C. for 20 min-30 min to acquire a dry polyimide film attached with the graphene.
